(19) United States
(12) Patent Application Publication
(10) Pub. No.: US 2026/0164703 A1
(43) Pub. Date: Jun. 11, 2026

(54) SEMICONDUCTOR STRUCTURES WITH REDUCED SHEET HEIGHT AND METHODS OF FORMING SAME

(71) Applicant: Taiwan Semiconductor Manufacturing Company, Ltd., Hsin-Chu (TW)

(72) Inventors: Jung-Piao CHIU, Kaohsiung City (TW); Jui-Lin CHEN, Taipei City (TW); Yu-Bey WU, Hsinchu City (TW)

(21) Appl. No.: 18/971,616

(22) Filed: Dec. 6, 2024

(51) Int. Cl. H10D 30/00; H10B 10/00; H10D 30/01; H10D 30/67; H10D 62/10; H10D 64/01

(52) U.S. Cl. CPC H10D 30/506; H10B 10/125; H10D 30/0194; H10D 30/508; H10D 30/6735; H10D 62/121; H10D 64/017

(57) ABSTRACT

A method includes providing a structure. The structure includes a substrate, a first stack of alternating first channel layers and first sacrificial layers over the substrate, a first source/drain trench exposing sidewalls of the first sacrificial layers, a second stack of alternating second channel layers and second sacrificial layers over the substrate, and a second source/drain trench exposing sidewalls of the second sacrificial layers. The method further includes performing a first etching process to selectively remove the first sacrificial layers and the second sacrificial layers, performing a second etching process to the first channel layers but not the second channel layers, forming a first source/drain feature in the first source/drain trench and a second source/drain feature in the second source/drain trench, and forming a first gate structure wrapping around the first channel layers and a second gate structure wrapping around the second channel layers.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. Integrated circuits include a variety of circuit device components, such as transistors. Transistors with different configurations may be suitable for different circuit functions due to their different performance characteristics. While existing transistors and methods for forming transistors are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor structure, according to one or more aspects of the present disclosure.

FIGS. 2A and 2B illustrates simplified block diagrams of a semiconductor structure that includes structures fabricated according to method of FIG. 1, according to various aspects of the present disclosure.

FIGS. 3, 4, 5, 6, 7, 8, 9, 10A, 10B, 11A, 11B, 12A, 12B, 14A, 14B, 15A, 15B, 16A, 16B, 17A, 17B, 18A, 18B, 19A, 19B, 20A, 20B, 21A, and 21B illustrate fragmentary cross-sectional views of an exemplary semiconductor structure during various fabrication stages in the method of FIG. 1, according to one or more aspects of the present disclosure.

FIGS. 13A and 13B illustrate enlarged alternative views of a portion of the exemplary semiconductor structure in FIG. 12A, according to one or more aspects of the present disclosure.

FIG. 22 illustrates an exemplary circuit schematic for a static random-access memory (SRAM) cell, according to various aspects of the present disclosure.

FIG. 23 illustrates a fragmentary layout view of the SRAM cell, according to various aspects of the present disclosure.

FIGS. 24A and 24B illustrate fragmentary top views of an alternative semiconductor structure during various fabrication stages in the method of FIG. 1, according to one or more aspects of the present disclosure.

FIG. 25 illustrates a fragmentary cross-sectional view of the alternative semiconductor structure along line C-C′ as in FIG. 24A, according to one or more aspects of the present disclosure.

FIGS. 26 and 27 illustrate fragmentary top views of an alternative semiconductor structure during various fabrication stages in the method of FIG. 1, according to one or more aspects of the present disclosure.

FIGS. 28 and 29 illustrate fragmentary cross-sectional views of the alternative semiconductor structure along line C-C′ and line D-D′ as in FIG. 26, respectively, according to one or more aspects of the present disclosure.

FIGS. 30A and 30B illustrate fragmentary top views of an alternative semiconductor structure during various fabrication stages in the method of FIG. 1, according to one or more aspects of the present disclosure.

FIG. 31 illustrates a fragmentary cross-sectional view of the alternative semiconductor structure along line C-C′ as in FIG. 30A, according to one or more aspects of the present disclosure.

FIG. 32 illustrates another exemplary circuit schematic for a static random-access memory (SRAM) cell, according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Static Random Access Memory (SRAM) is a semiconductor memory that retains data statically as long as it is powered. Unlike dynamic RAM (DRAM), SRAM is faster and more reliable, eliminating the need for constant refreshing. A semiconductor device (e.g., an SRAM macro) may include memory cells in a memory cell region and logic cells in a logic cell region. The memory cells are also referred to as bit cells, and are configured to store memory bits. The memory cells may be arranged in rows and columns in forming an array. The logic cells may be standard cells (STD cells), such as inventor (INV), AND, OR, NAND, NOR, Flip-flip, SCAN and so on. The logic cell region is disposed adjacent to the memory cell region, and is configured to implement various logic functions. As integrated circuit (IC) technologies progress towards smaller technology nodes, multi-gate structures, such as fin-like field effect transistors (FinFETs) or gate-all-around (GAA) transistors, are integrated into SRAM cells to enhance performance.

GAA transistors may also be referred to as nanosheet transistors or nanowire transistors. They can be either n-type or p-type. GAA transistors may have channel regions disposed in nanowire channel members, bar-shaped channel members, nanosheet channel members, nanostructure channel members, bridge-shaped channel members, and/or other suitable channel configurations.

In some existing technologies, the formation of GAA transistors includes forming a number of channel layers interleaved by a number of sacrificial layers and performing a channel release process to selectively remove the sacrificial layers to release the channel layers as channel members. However, sheet height uniformity of the channel layers may become a limit in further scaling down of the GAA transistors. While existing techniques are generally adequate for their intended purposes, they are not satisfactory in all aspects.

The present disclosure provides methods of forming a semiconductor structure. The semiconductor structure includes a first region and a second region. In some embodiments, the first region includes a memory region and the second region includes a peripheral region. In an example process, a fin-shaped structure with channel layers and sacrificial layers is formed in each of the first and second regions. After formation of a dummy gate stack over a channel region of the fin-shaped structure, at least one gate spacer is formed over the dummy gate stack. Source/drain regions of the fin-shaped structure are recessed. The sacrificial layers are selectively removed to release the channel layers as channel members. In some embodiments, a mask layer is then formed in the second region while exposing the first region. The channel members in areas (e.g., the first region) not covered by the mask layer are etched to reduce channel thickness. Thereafter, the mask layer is removed from the second region. A dummy layer may be deposited around the channel members. After forming inner spacer features and source/drain features, the dummy gate stack and the dummy layer may be selectively removed to release the channel members again. Further processes are then performed to finish the fabrication of the semiconductor structure. In some other embodiments, the first region includes a sub-region where p-type transistors are formed, and the mask layer is formed in the sub-region and the second region. In yet some other embodiments, the first region includes a sub-region where p-type transistors and pull-down transistors of SRAM cells are formed, and the mask layer is formed in the sub-region and the second region. In yet some other embodiments, the first region includes a sub-region where n-type transistors are formed, and the mask layer is formed in the sub-region and the second region. By forming the mask layer over certain areas and performing an etching process to the channel members in uncovered areas, channel member thicknesses in different areas of the semiconductor structure may be different, performance of the different regions may be improved, thus overall performance of the semiconductor structure may be improved.

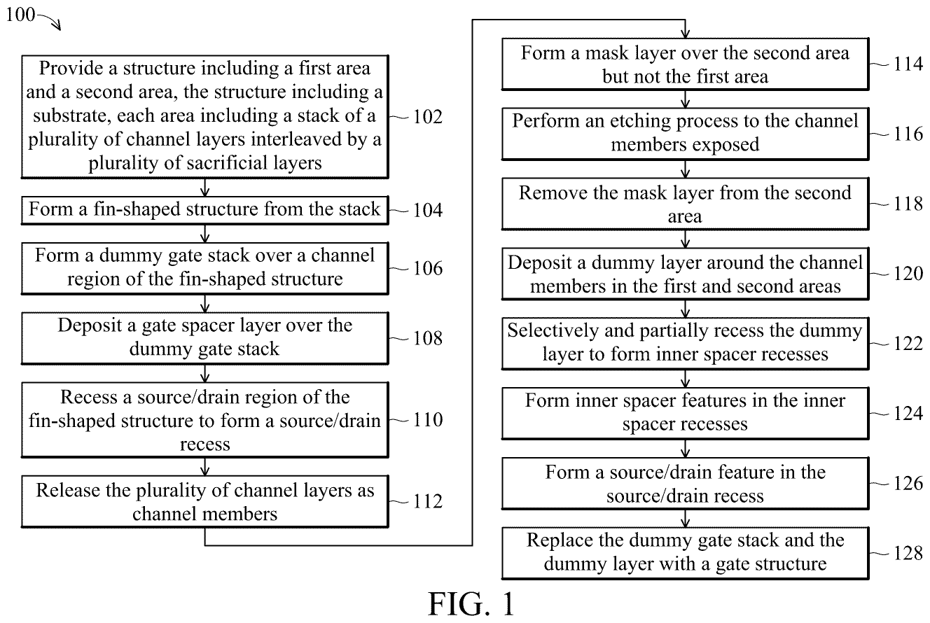

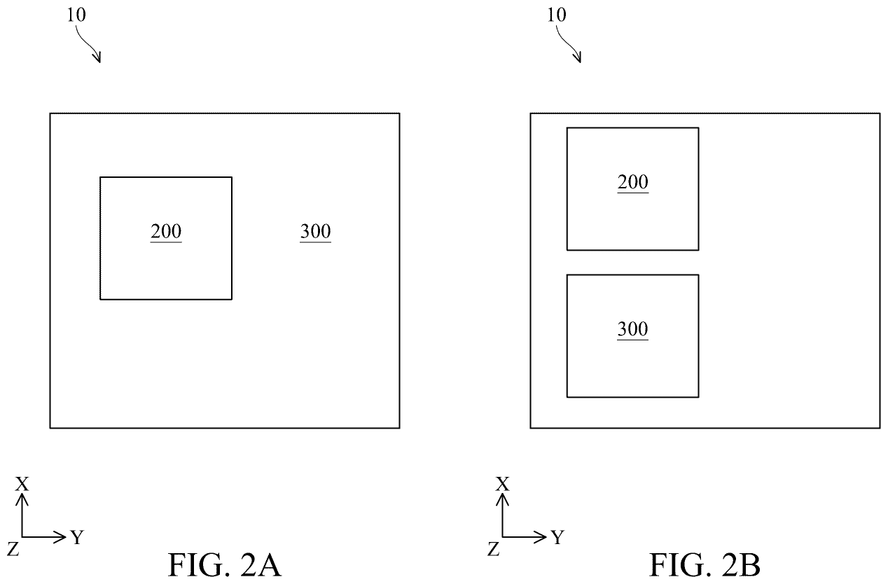

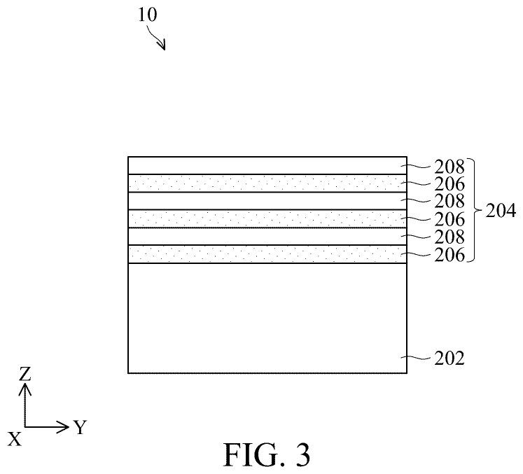

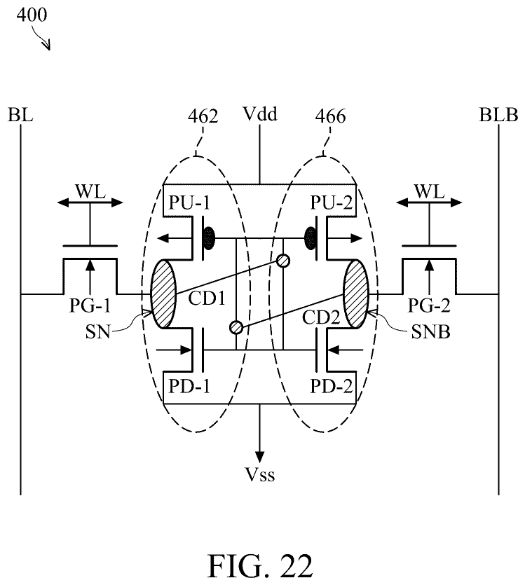

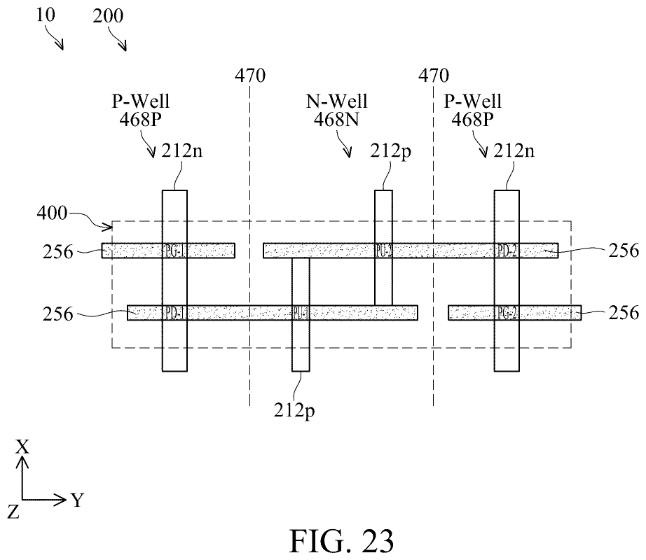

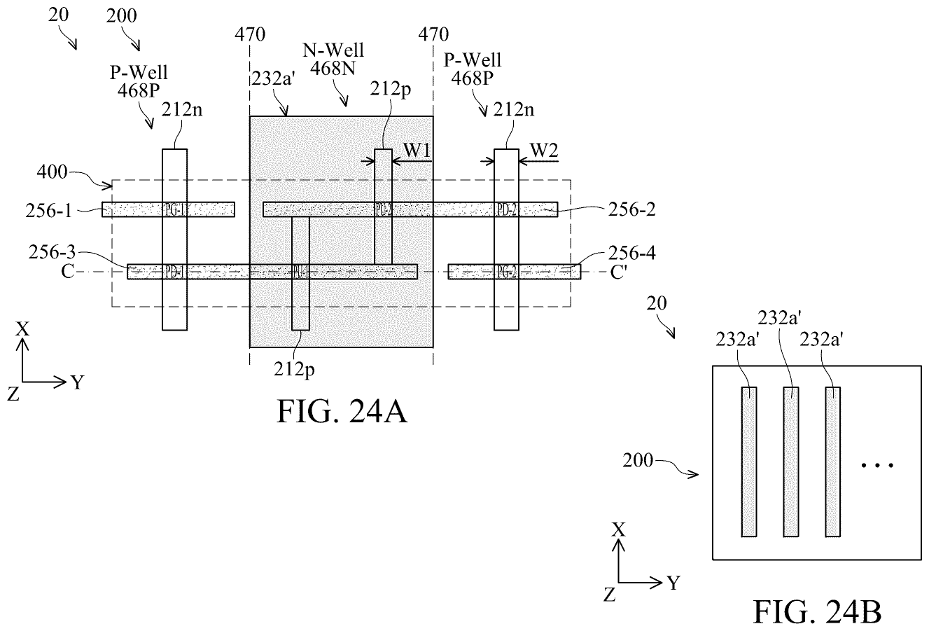

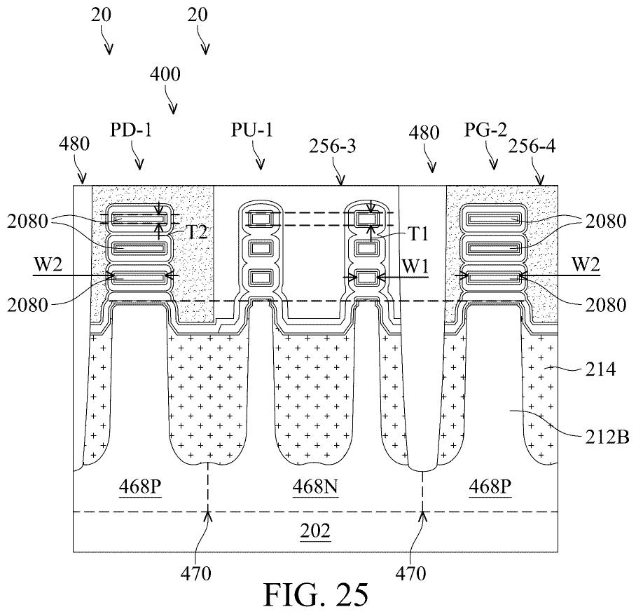

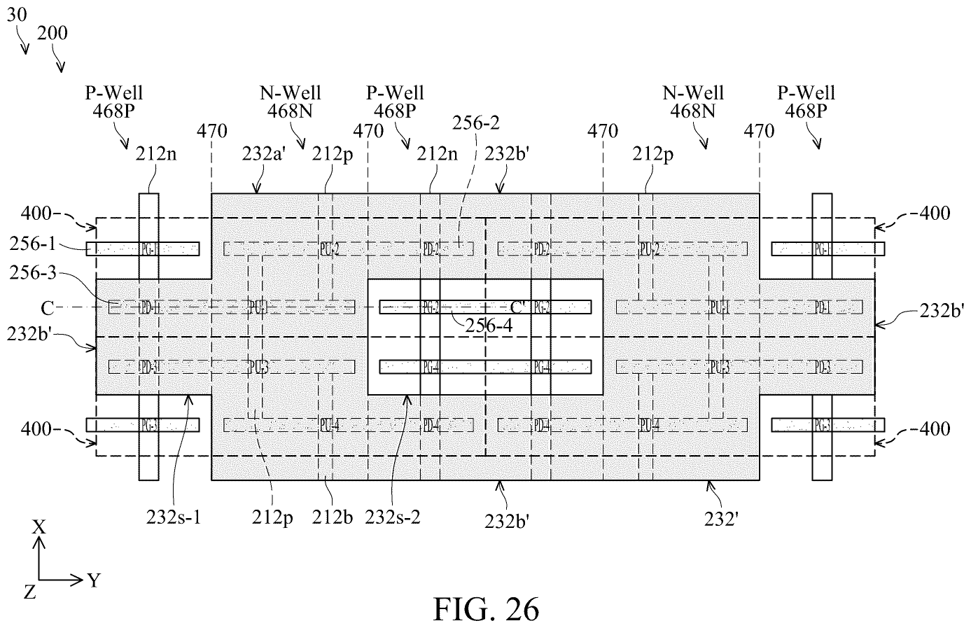

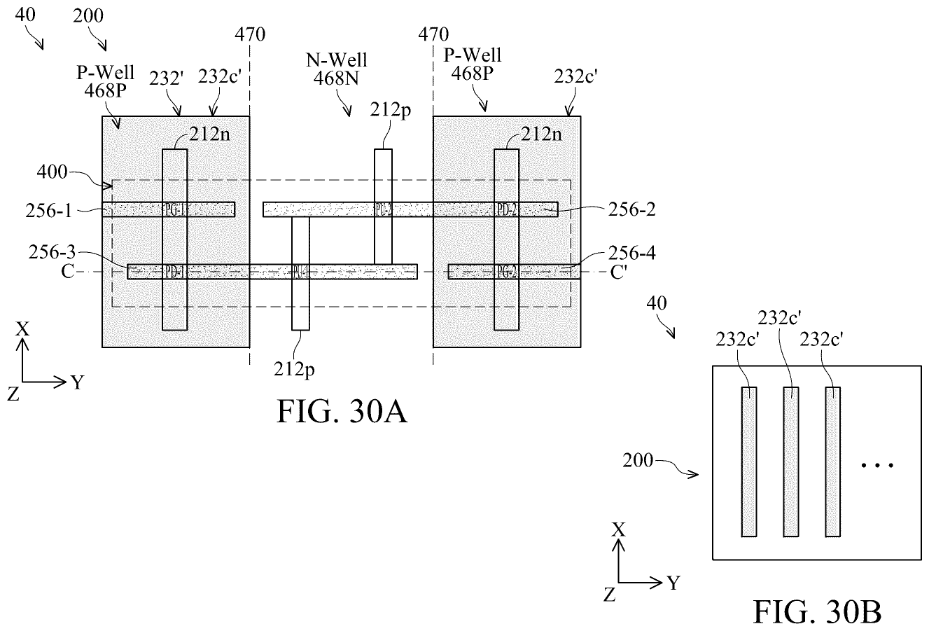

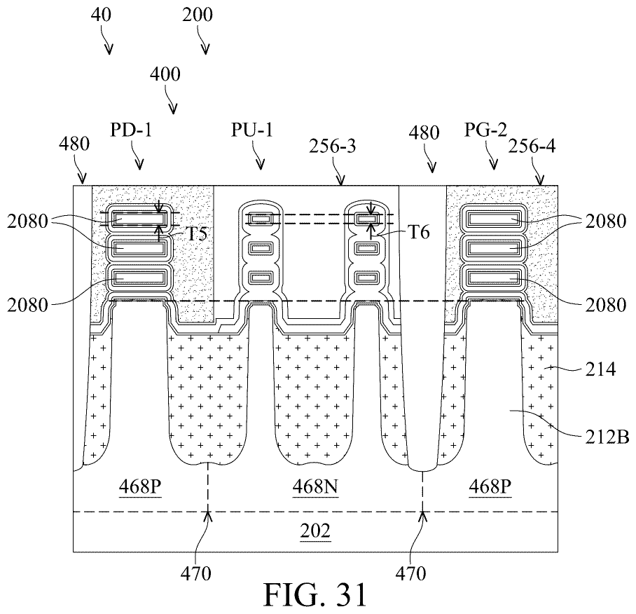

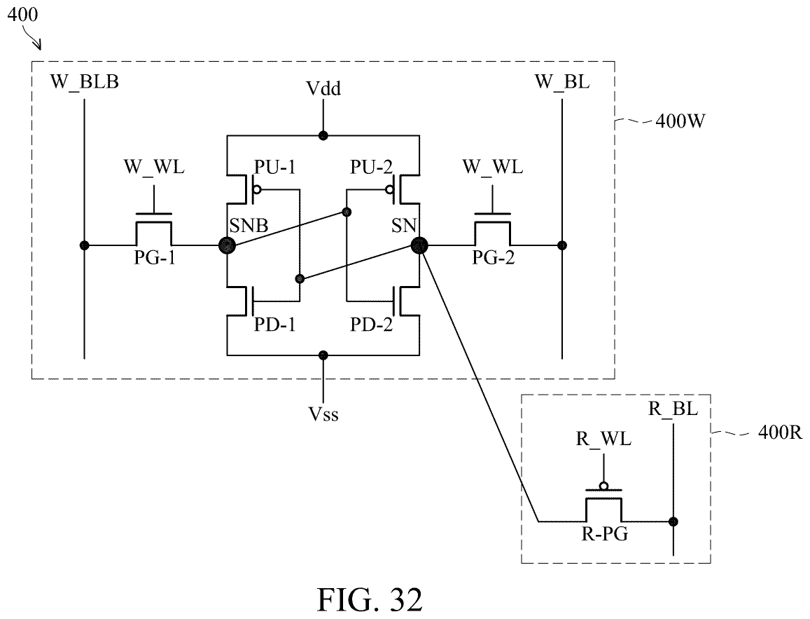

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2A-21B. FIGS. 2A-2B are simplified block diagrams of a structure 10 that includes semiconductor structures fabricated according to method 100 of FIG. 1. FIGS. 3-21B are fragmentary cross-sectional views of the structure 10 at different stages of fabrication according to embodiments of method 100 in FIG. 1. FIG. 22 illustrates an exemplary circuit schematic for an SRAM cell according to various aspects of the present disclosure. FIG. 23 illustrates a fragmentary layout view of the SRAM cell according to various aspects of the present disclosure. FIGS. 24A-25 are fragmentary top or cross-sectional views of an alternative structure 20 at different stages of fabrication according to embodiments of method 100 in FIG. 1. FIGS. 26-29 are fragmentary top or cross-sectional views of another alternative structure 30 at different stages of fabrication according to embodiments of method 100 in FIG. 1. FIGS. 30-31 are fragmentary top or cross-sectional views of yet another alternative structure 40 at different stages of fabrication according to embodiments of method 100 in FIG. 1. FIG. 32 illustrates another exemplary circuit schematic for a static random-access memory (SRAM) cell, according to various aspects of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of method 100. Not all steps are described herein in detail for reasons of simplicity. Because the structure 10 (or 20, 30, 40) will be fabricated into a semiconductor structure or a semiconductor device, the structure 10 may be referred to herein as a semiconductor structure 10 (or 20, 30, 40) or a semiconductor device 10 (or 20, 30, 40) as the context requires. For avoidance of doubts, the X, Y and Z directions in FIGS. 2A-21B and 23-31 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Referring to FIGS. 1 and 2A-2B, method 100 may be applied to form an IC structure (e.g., the structure 10). The semiconductor structure 10 may include, e.g., a microchip, a microprocessor, an application specific integrated circuit (ASIC), a field programmable gate array (FPGA), a digital signal processor (DSP), or a portion thereof, various passive and active microelectronic devices such as resistors, capacitors, inductors, diodes, p-type field effect transistors (PFETs), n-type field effect transistors (NFETs), FinFET, gate-all-around (GAA) transistors (such as nanosheet FETs or nanowire FETs), other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. The exact functionality of the semiconductor device 10 is not a limitation to the provided subject matter.

Referring to FIGS. 2A-2B, the structure 10 may include a first region 200 and a second region 300. In the depicted embodiment in FIG. 2A, the first region 200 is surrounded by the second region 300. In the depicted embodiment in FIG. 2B, the first region 200 and the second region 300 are spaced apart from each other. In some embodiments not depicted, the first region 200 and the second region 300 are positioned in close proximity to each other. In some embodiments, the semiconductor structure 10 includes more than one first region 200 and more than one second region 300. FIGS. 2A and 2B have been simplified for the sake of clarity to better understand the inventive concepts of the present disclosure. Additional features can be added in the structure, and some of the features described below can be replaced, modified, or eliminated in other embodiments of the structure.

In some embodiments, the first region 200 includes a memory region and is referred to as a memory region 200. The memory region 200 may include at least an array of memory cells arranged in rows and columns. The array may include static random-access memory (SRAM) cells, dynamic random-access memory (DRAM) cells, non-volatile random-access memory (NVRAM) cells, flash memory cells, other suitable memory cells, or combinations thereof. In an embodiment, the array includes a number of SRAM cells, which generally provide memory or storage capable of retaining data when power is applied. In some embodiments, each SRAM cell includes one or more transistors described below.

In some embodiments, the second region 300 includes a peripheral region and is referred to as a peripheral region 300. The peripheral region 300 may include a logic region that includes logic cells. The logic cells are configured to implement various logic functions. In some embodiments, the logic cells are configured to implement various logic functions to the memory cells in the memory region 200. The logic functions of the logic cells include, for example, write and/or read decoding, word line selecting, bit line selecting, data driving and memory self-testing. The logic functions of the logic cells described above are given for the explanation purpose. Various logic functions of the logic cells are within the contemplated scope of the present disclosure.

The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on fork-sheet devices, complementary FET (CFET) devices, and the like. CFET devices include a first transistor of a first conductivity type (e.g., n-type or p-type) vertically stacked over a second transistor having an opposite conductivity type. In some examples, GAA transistors may be used to implement CFET devices. One of ordinary skill may recognize other embodiments of semiconductor devices that may benefit from aspects of the present disclosure.

Referring to FIGS. 1 and 3, method 100 includes a block 102 where a structure 10 is provided. As shown in FIG. 3, the structure 10 includes a substrate 202 and a stack 204 of alternating semiconductor layers formed over the substrate 202. The first region 200 and the second region 300 may include portions of the same substrate 202. In some embodiments, the first region 200 and the second region 300 include portions of the same stack 204. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 3, which is for illustrative purposes only and not intended to be limiting beyond what is specifically recited in the claims. It can be appreciated that any number of epitaxial layers may be formed in the stack 204. The number of layers depends on the desired number of channel members for the semiconductor structure 10. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

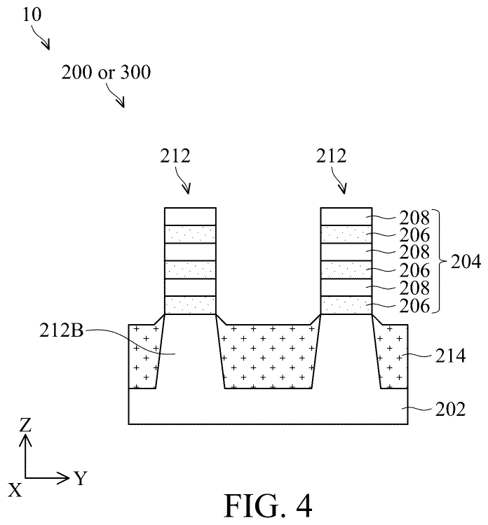

In some embodiments, FIGS. 4-9 represent embodiments of structures in the first region 200 or in the second region 300 at different stages of fabrication. Referring to FIGS. 1 and 4, method 100 includes a block 104 where a fin-shaped structure 212 (also referred to as an active region 212) is formed from the stack 204 and the substrate 202. The fin-shaped structure 212 may be formed in each of the first region 200 and the second region 300. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 4, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 4, the fin-shaped structure 212 that includes the sacrificial layers 206 and the channel layers 208 extends vertically along the Z direction and lengthwise along the X direction. As shown in FIG. 4, the fin-shaped structure 212 includes a base fin structure 212B patterned from the substrate 202. The patterned stack 204, including the sacrificial layers 206 and the channel layers 208, is disposed directly over the base fin structure 212B.

An isolation feature 214 is formed adjacent to the fin-shaped structure 212. In some embodiments represented in FIG. 4, the isolation feature 214 is disposed on sidewalls of the base fin structure 212B. In some embodiments, the isolation feature 214 may be formed in the trenches to isolate the fin-shaped structures 212 from a neighboring fin-shaped structure 212. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 4. The fin-shaped structure 212 rises above the STI feature 214 after the recessing, while the base fin structure 212B is embedded or buried in the isolation feature 214.

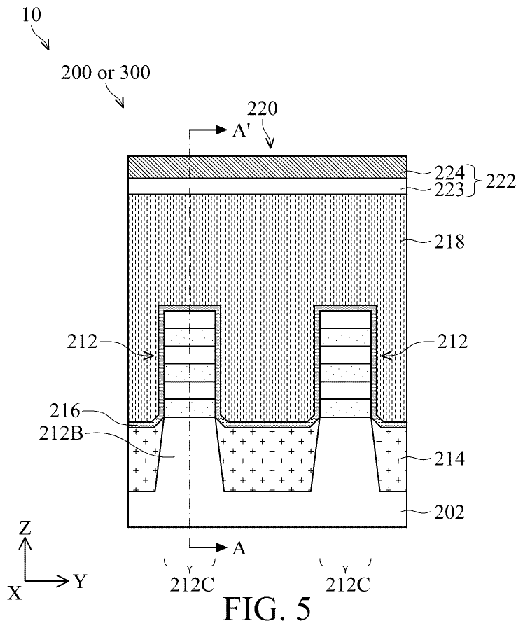

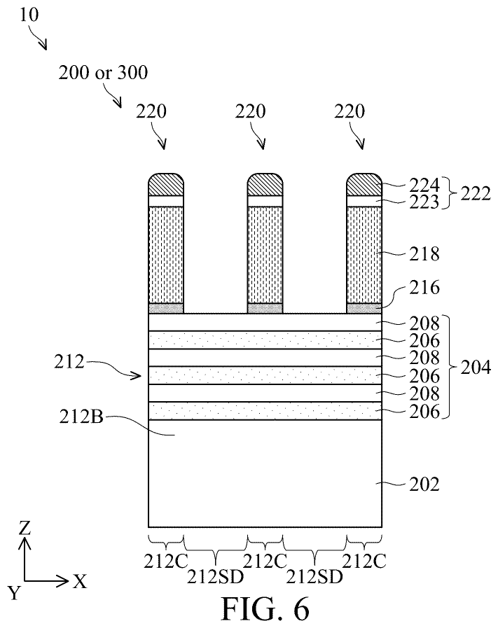

Referring to FIGS. 1, 5, and 6, method 100 includes a block 106 where a dummy gate stack 220 is formed over a channel region 212C of the fin-shaped structure 212. FIG. 6 illustrates a fragmentary cross-section view of the structure 10 taken along line A-A′ as in FIG. 5. In some embodiments, a gate replacement process (or gate-last process) is adopted where the dummy gate stack 220 (shown in FIGS. 5 and 6) serves as a placeholder to undergo various processes and is to be removed and replaced by a functional gate structure. Other processes and configuration are possible. In some embodiments illustrated in FIG. 6, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 6, the channel region 212C is disposed between two source/drain regions 212SD along the X direction.

The formation of the dummy gate stack 220 may include deposition of layers in the dummy gate stack 220 and patterning of these layers. Referring to FIG. 5, a dummy dielectric layer 216, a dummy electrode layer 218, and a gate-top hard mask layer 222 may be blanketly deposited over the first region 200 and the second region 300. In some embodiments, the dummy dielectric layer 216 may be formed on the fin-shaped structure 212 using a chemical vapor deposition (CVD) process, an atomic layer deposition (ALD) process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 6. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 6, the dummy gate stack 220 is patterned such that it is only disposed over the channel region 212C, not disposed over the source/drain region 212SD.

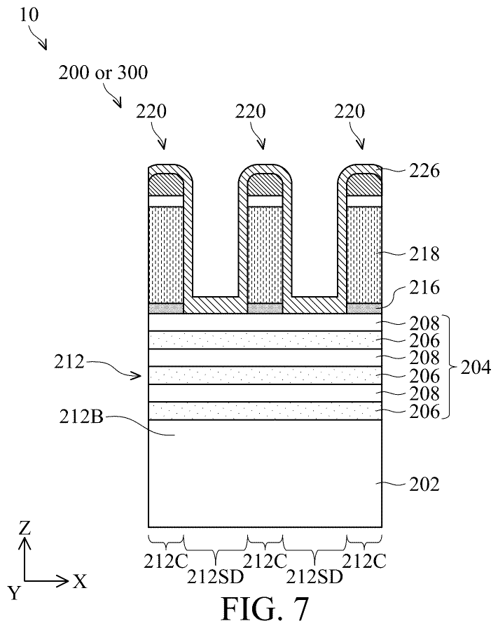

Referring to FIGS. 1 and 7, method 100 includes a block 108 where a gate spacer layer 226 is deposited over the structure 10, including over the dummy gate stack 220. In some embodiments, the gate spacer layer 226 is deposited conformally over the first region 200 and the second region 300, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

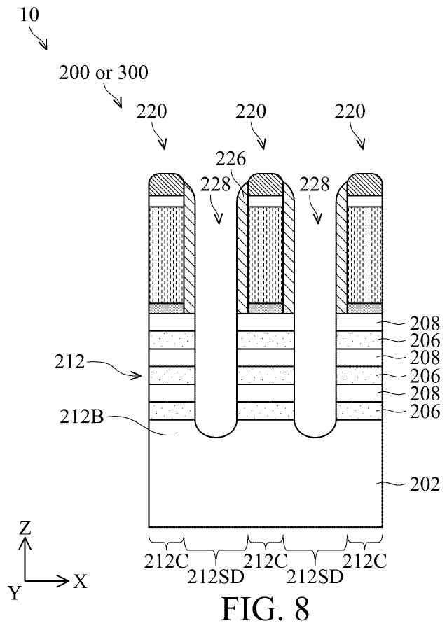

Referring to FIGS. 1 and 8, method 100 includes a block 110 where a source/drain region 212SD of the fin-shaped structure 212 is anisotropically recessed to form a source/drain trench 228. The anisotropic etch may include a dry etch or a suitable etch process that etches the gate spacer layer 226, the source/drain regions 212SD and a portion of the substrate 202 below the source/drain regions 212SD. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 8, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202.

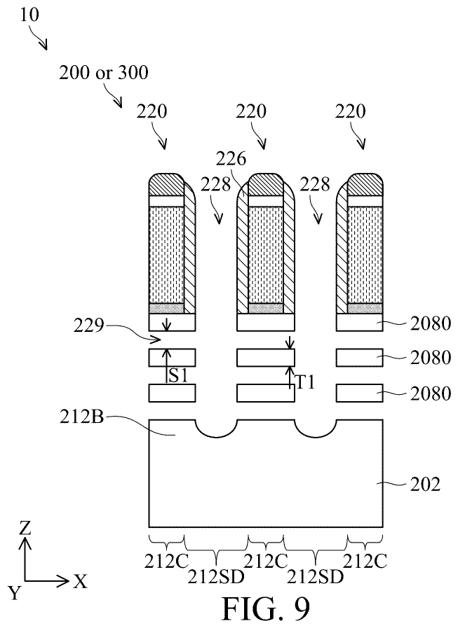

Referring to FIGS. 1 and 9, method 100 includes a block 112 where the plurality of channel layers 208 in the channel regions 212C are released as channel members 2080. After the formation of the source/drain trench 228, the sacrificial layers 206 interleaving the channel layers 208 in the channel region 212C are selectively removed. The selective removal of the sacrificial layers 206 releases the channel layers 208 (shown in FIG. 8) to form channel members 2080 shown in FIG. 9. In the embodiments where the channel members 2080 include silicon and the sacrificial layers 206 include silicon germanium, the selective removal of the sacrificial layers 206 removes at least a portion of germanium impurities in the channel members 2080 that diffuse from the sacrificial layer 206. The selective removal of the sacrificial layers 206 forms spaces 229 between adjacent channel members 2080. In some embodiments, the channel members 2080 have a thickness (or sheet height) T1 along the Z-direction, and the space 229 has a height S1 along the Z-direction. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Depending on the design, the channel members 2080 may take form of nanowires, nanosheets, or other nanostructures. By implementing operations at block 112, uniformity of the thickness of the channel members 2080 may be increased.

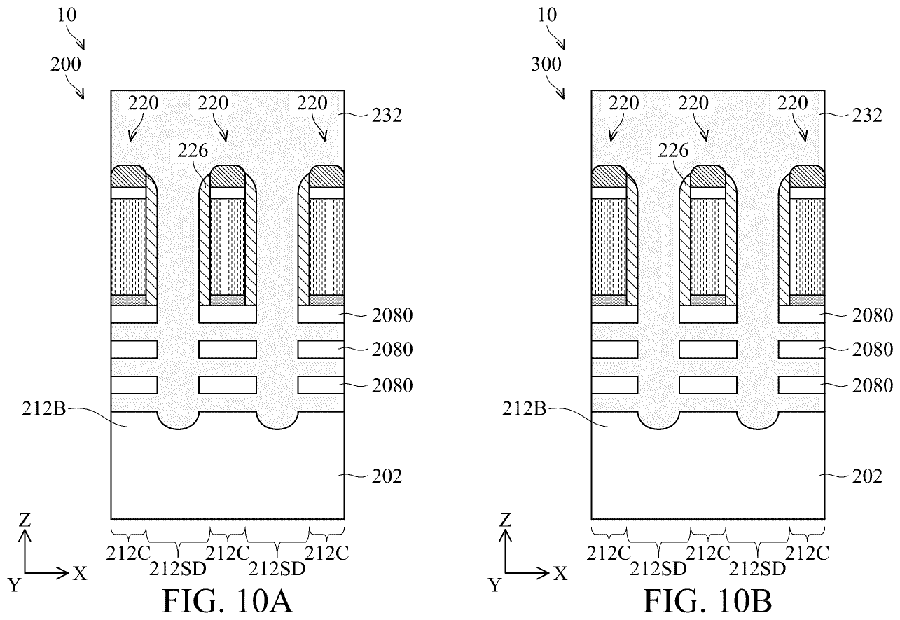

In some embodiments, FIGS. 10A-12A and 14A-21A represent embodiments of structures in the first region 200 at different stages of fabrication, FIGS. 10B-12B and 14B-21B represent embodiments of structures in the second region 300 at different stages of fabrication.

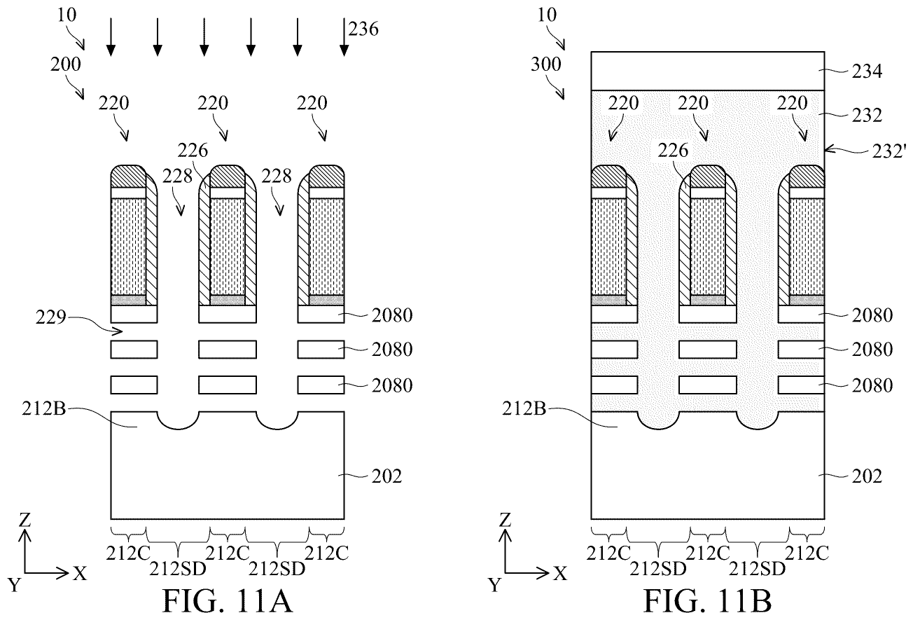

Referring to FIGS. 1 and 10A-11B, method 100 includes a block 114 where a mask layer is formed over a second area (e.g., the second region 300) of the structure 10 but not over a first area (e.g., the first region 200) of the structure 10. Operations at block 114 may include depositing a mask material 232 over the first region 200 and the second region 300 (FIGS. 10A-10B), forming a patterned photoresist layer 234 over the mask material 232 in the second portion but not the first portion (FIGS. 11A-11B), and etching the mask material 232 in the first region using the patterned photoresist layer 234 as an etch mask (FIGS. 11A-11B). Block 114 is optional and may be omitted in some embodiments.

In some embodiments, the mask material 232 includes a bottom antireflective coating (BARC) material and provides a platform for photoresist coating and photoresist patterning. The BARC material may include silicon oxynitride (SiON), silicon oxycarbide, a polymer, or other suitable materials. In an embodiment, the mask material 232 is formed by any suitable process, such as CVD, or spin coating a BARC material over the substrate 202 and filling the source/drain trenches 228 and the openings 229, and baking the BARC material to cause cross-linking within the BARC material.

Referring to FIGS. 11A-11B, the mask material 232 in the first region 200 is removed. After forming the mask material 232, a patterned photoresist layer 234 is formed over the mask material 232. In an example process, a photoresist layer may be blanketly deposited over the structure 10, including over the mask material 232 in the first region 200 and the second region 300. The photoresist layer is then exposed to radiation going through or reflected from a mask, baked in a post-bake process, and developed in a developer solution to form the patterned photoresist layer 234, as represented in FIGS. 11A-11B. In this illustrated embodiment, the patterned photoresist layer 234 is formed in the second region 300 and is not formed in the first region 200. An etching process 236 is then performed to recess the mask material 232 while using the patterned photoresist layer 234 as an etch mask. The etching process 236 may include an isotropic etching process or anisotropic etching process. The etching process 236 may include use of a dry etch process. The dry etch process may include use of plasma of argon (Ar), oxygen (O₂), nitrogen (N₂), hydrogen (H₂), or a combination thereof. After removing the mask material 232 from the area (e.g., the first region 200) not covered by the patterned photoresist layer 234, the remaining mask material 232 in the second region 300 becomes the mask layer 232′. The patterned photoresist layer 234 may be selectively removed. In some cases, the patterned photoresist layer 234 may be removed during or after the etching process 236. Upon completion of operations at block 114, the channel members 2080 in the first region 200 may be exposed in the source/drain trenches 228 and the openings 229.

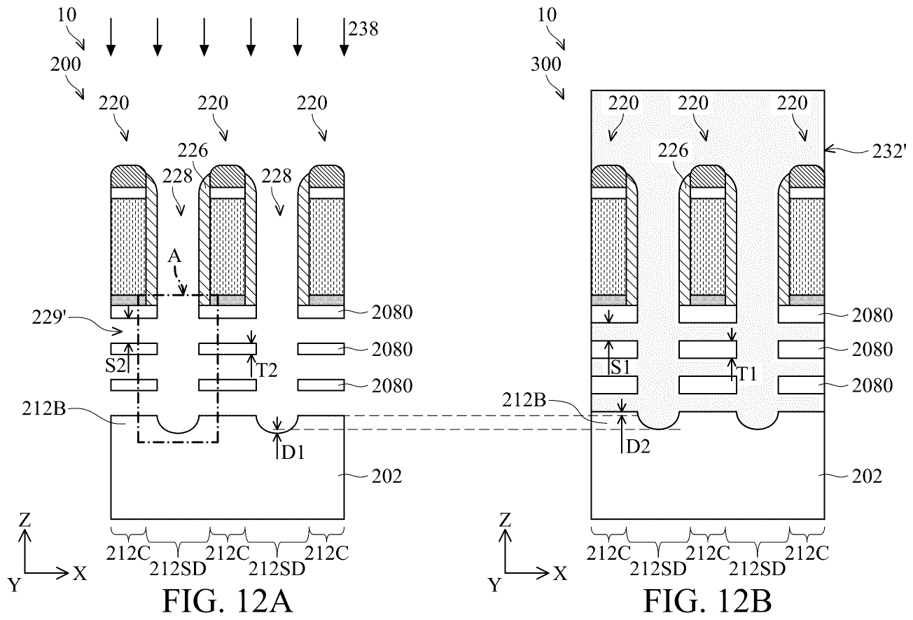

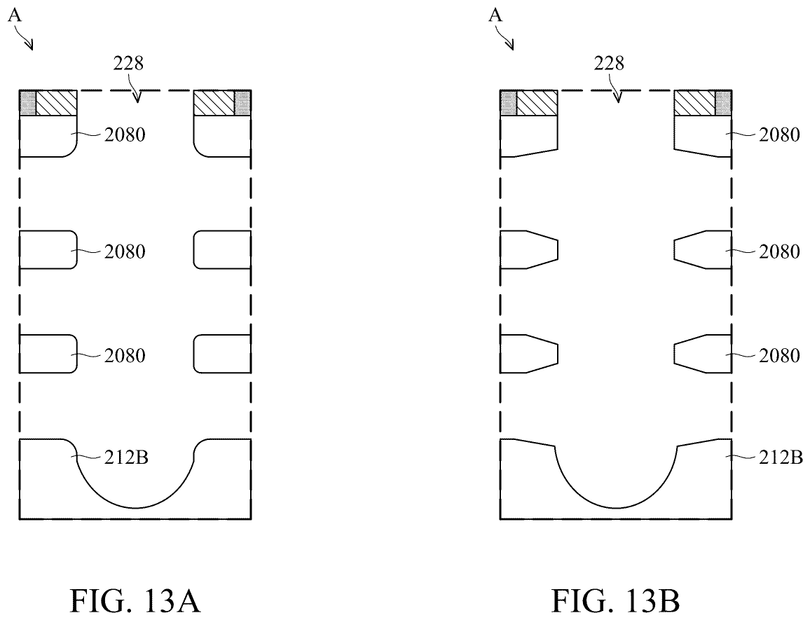

Referring to FIGS. 1 and 12A-13B, method 100 includes a block 116 where an etching process 238 is performed to the channel members 2080 in the first region 200. FIGS. 13A and 13B illustrate enlarged alternative views of a portion A in FIG. 12A. During operations at block 116, the channel members 2080 in the second region 300 are protected from contacting etchants by the mask layer 232′. The dummy gate stack 220 in the first region 200 may be protected from being damaged during the etching process 238 by the gate spacer layer 226 and the gate-top hard mask layer 222. The etching process 238 trim (i.e., remove a portion of) the channel members 2080 exposed in the source/drain trenches 228 and the openings 229, thereby forming enlarged openings 229′. The etching process 238 may include selective dry etch, selective wet etch, or other selective etch processes. In some embodiments, the etching process 238 may be a selective isotropic dry etching process that selectively etches a portion of the channel members 2080. In some embodiments where the germanium impurities from the sacrificial layer 206 is not completely removed during operations at block 112, the etching process 238 removes a remaining portion of the germanium impurities in the channel members 2080. The extent at which the channel members 2080 are recessed is controlled by duration of the etching process. In an embodiment, the selective dry etching process may include use of one or more fluorine-based etchants, such as fluorine gas or hydrofluorocarbons. In some embodiments, the etching process 238 is different from the etching process implemented at block 112. For example, the etching process implemented at block 112 includes a selective wet etching and is performed at a first chamber, the etching process 238 includes a selective dry etching and is performed at a second chamber different from the first chamber.

Upon completion of operations at block 116, referring to FIGS. 12A and 12B, the channel members 2080 in the first region 200 may have a thickness (or sheet height) T2 of about 4 nm to about 5 nm along the Z-direction, and the enlarged openings 229′ may have a height S2 along the Z-direction. T2 may be less than T1 as described above in the second region 300, and S2 may be greater than S1 as described above in the second region 300. A ratio of S1 to S2 may be about 0.6 to 1. In some embodiments, a ratio of T2 to T1 is about 0.7 to 1. If the ratio of T2 to T1 is too small, T2 is too small, and channel resistance of the channel members 2080 in the first region 200 may be too large.

Top surfaces of the base fin structure 212B in the source/drain regions 212SD and in the channel regions 212C in the first region 200 may be lower than corresponding top surfaces of the base fin structure 212B in the second region 300 by distances D1 and D2, respectively, as depicted in FIGS. 12A and 12B. D1 (or D2) may be about half of a difference between T1 and T2 (or about half of a difference between S1 and S2). A horizontal center line of a channel member 2080 (e.g., a bottommost channel member 2080) in the first region 200 may align with a horizontal center line of a corresponding channel member 2080 (e.g., a bottommost channel member 2080) in the second region 300.

In some embodiments, the channel members 2080 in the first region 200 have a rectangular shape in the cross-sectional view as depicted in FIG. 12A. In some other embodiments as in FIG. 13A, corners of the channel members 2080 and the base fin structure 212B may be rounded during the etching process 238. In some other embodiments as in FIG. 13B, during the etching process 238, end portions of the channel members and the base fin structure 212B are etched more than middle portions thereof, thus top and bottom surfaces of the end portions may be tilted as depicted.

As described above, operations at block 112 may reduce the germanium impurities in the channel members 2080 in the first region 200 and the second region 300. The etching process 238 may further reduce the germanium impurities in the channel members 2080 in the first region 200. In the embodiments where the first region 200 includes SRAM cells, by implementing the present disclosed method 100 (e.g., operations at blocks 112 to 116), uniformity of the thickness of the channel members 2080 may be increased, threshold voltage (Vt) variation, minimum operating voltage Vmin, and short channel effect of the SRAM cells may be reduced. Vmin may be the lowest voltage at which an SRAM cell can be read. Lower Vmin may result in lower power consumption. In addition, the channel members 2080 in the second region 300 may have a relatively larger thickness, which allows for a larger current and improves the performance of the second region 300. Thus, the overall performance of the structure 10 may be improved.

In the embodiments where operations at block 114 is omitted, the etching process 238 is performed to the channel members 2080 in both the first region 200 and the second region 300. In such embodiments, the ratio of T2 to T1 is equal to 1.

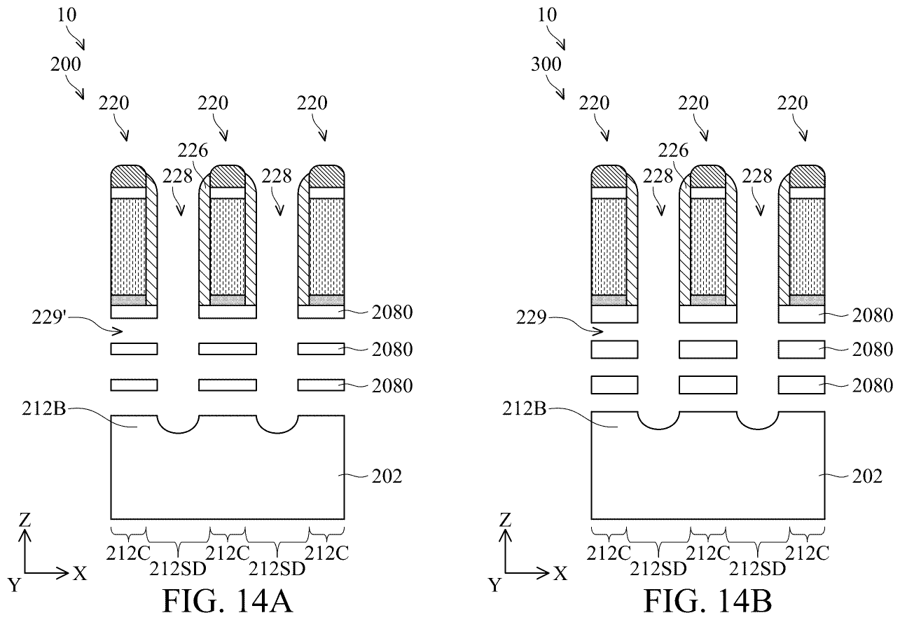

Referring to FIGS. 1 and 14A-14B, method 100 includes a block 118 where the mask layer 232′ is selectively removed from the second region 300. One or more etching processes may be performed to selectively remove the mask layer 232′ without substantially etching other features (e.g., the channel members 2080, the base fin structure 212B, the gate spacer layer 226). The mask layer 232′ may be removed using an ashing process or a dry etch process that includes use of plasma of argon (Ar), oxygen (O₂), nitrogen (N₂), hydrogen (H₂), or a combination thereof. In the embodiments where block 114 is omitted, block 118 is omitted.

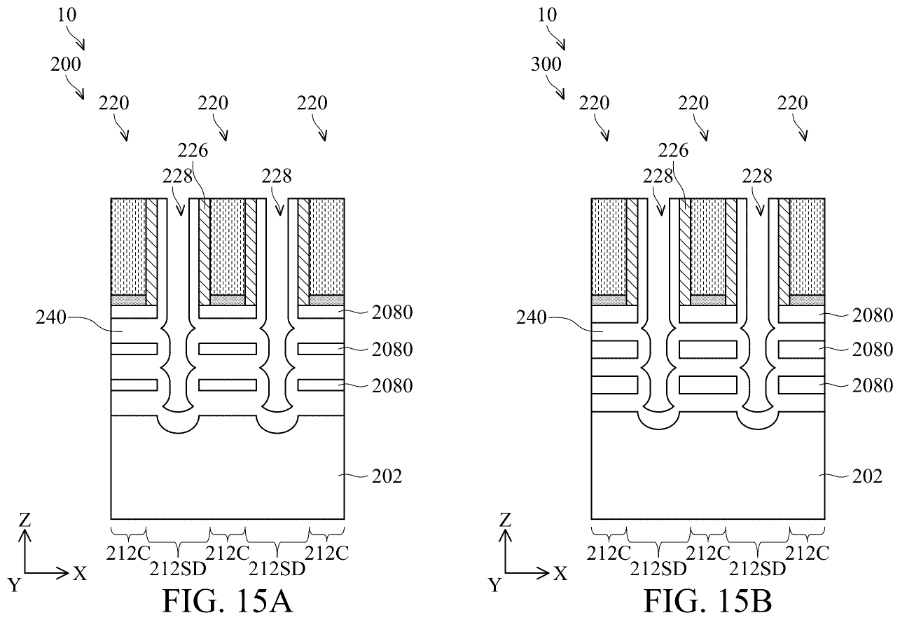

Referring to FIGS. 1 and 15A-15B, method 100 includes a block 120 where a dummy layer 240 is deposited around the channel members 2080 and over the source/drain trench 228 in the first region 200 and the second region 300. The dummy layer 240 may include a dielectric material. The dielectric material may include an oxide, a nitride, a carbide, or a combination thereof. Examples of the dielectric material may include silicon oxide, SiCO, SiN, SiCN, and aluminum oxide (e.g., Al₂O₃). In some embodiments, the dummy layer 240 includes silicon oxide and/or aluminum oxide. The dummy layer 240 may be deposited using plasma enhanced chemical vapor deposition (PECVD), an flowable CVD (FCVD), PEALD, ALD, or a rapid thermal oxidation (RTO) process. As shown in FIG. 15A-15B, the dummy layer 240 fills the enlarged opening 229′ in FIG. 14A (or the opening 229 in FIG. 14B) among the channel members 2080 and covers end sidewalls of the channel members 2080. Additionally, the dummy layer 240 is in direct contact with a sidewall of the gate spacer layer 226 and a top surface of the substrate 202 or the base fin structure 212B.

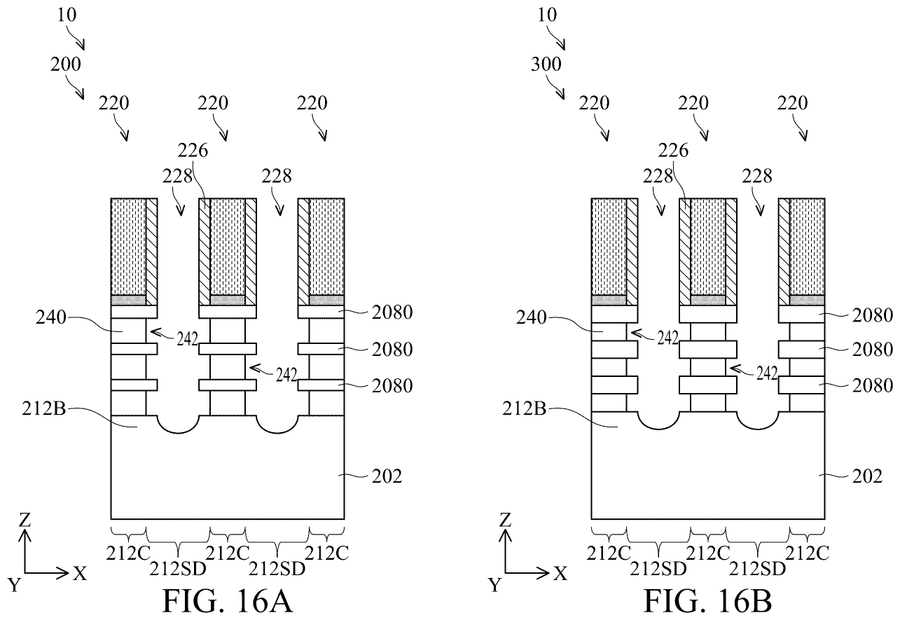

Referring to FIGS. 1 and 16A-16B, method 100 includes a block 122 where the dummy layer 240 is selectively and partially recessed to form inner spacer recesses 242 while the gate spacer layer 226, the dummy gate stack 220, the exposed portion of the substrate 202 or the base fin structure 212B, and the channel members 2080 are substantially unetched. In an embodiment where the channel members 2080 consist essentially of silicon (Si) and the dummy layer 240 is formed of silicon oxide, the selective recess of the dummy layer 240 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof.

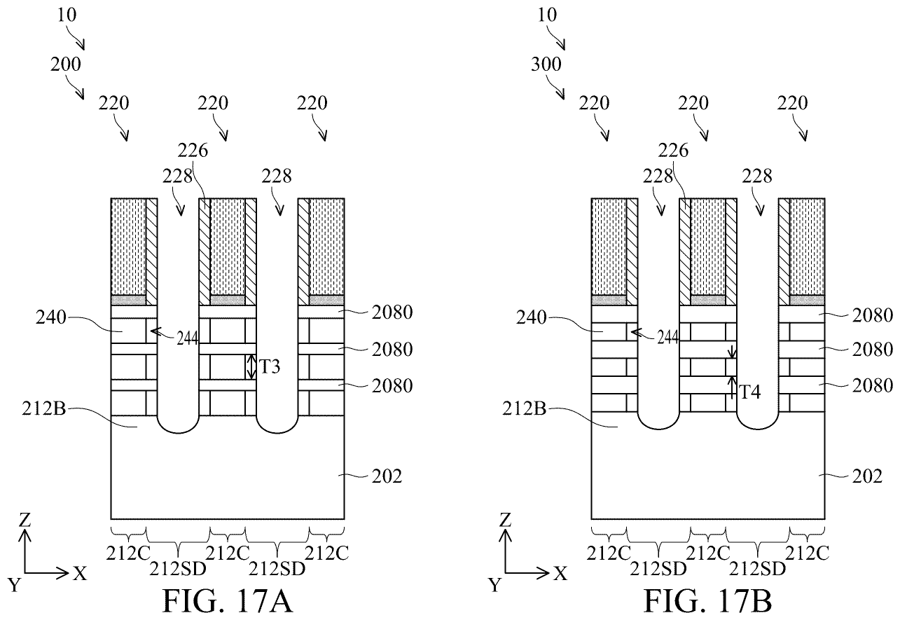

Referring to FIGS. 1 and 17A-17B, method 100 includes a block 124 where inner spacer features 244 are formed in the inner spacer recesses 238. While not shown explicitly, operation at block 124 may include deposition of inner spacer material over the structure 200, and etching back the inner spacer material to form the inner spacer features 244 in the inner spacer recesses 242 (shown in FIGS. 16A-16B). After the inner spacer recesses 242 are formed, an inner spacer material is deposited over the structure 10, including over the inner spacer recesses 242. The inner spacer material may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material may be a single layer or a multilayer. In some implementations, the inner spacer material may be deposited using CVD, PECVD, SACVD, ALD or other suitable methods. The inner spacer material is deposited into the inner spacer recesses 242 as well as over the sidewalls of the channel members 2080 exposed in the source/drain trenches 228. Referring to FIGS. 17A-17B, the deposited inner spacer material is then etched back to remove the inner spacer material from the sidewalls of the channel members 2080 to form the inner spacer features 244 in the inner spacer recesses 242. The inner spacer features 244 in the first region 200 may track the profiles of top and bottom surfaces of the end portions (e.g., as in FIGS. 12A, 13A-13B) of adjacent channel members 2080 (or the base fin structure 212B). In some embodiments, the inner spacer features 244 in the first region 200 have a first thickness T3 along the Z-direction, the inner spacer features 244 in the second region 300 have a second thickness T4 along the Z-direction. A ratio of T4 to T3 is about 0.6 to 1.

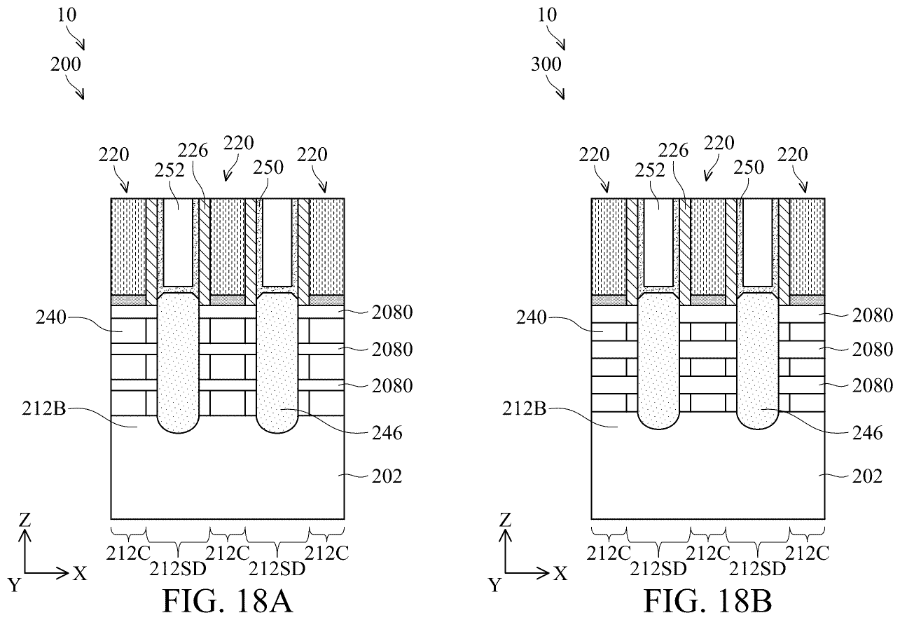

Referring to FIGS. 1 and 18A-18B, method 100 includes a block 126 where a source/drain feature 246 is formed over the source/drain region 212SD. While not explicitly shown, before any of the epitaxial layers are formed, method 100 may include a cleaning process to clean surfaces of the structure 10. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide, SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

Source/drain feature(s) 246 may refer to a source or a drain, individually or collectively dependent upon the context. The source/drain features 246 are coupled to the channel regions 212C. Each of the source/drain features 246 may be epitaxially and selectively formed from exposed semiconductor surfaces by using an epitaxial process, such as vapor phase epitaxy (VPE), ultrahigh vacuum chemical vapor deposition (UHV-CVD), molecular-beam epitaxy (MBE), and/or other suitable processes. Example n-type source/drain features may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Example p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In some embodiments, each of the n-type source/drain features and the p-type source/drain features may include multiple semiconductor layers with different doping concentrations. The n-type source/drain features and the p-type source/drain features may be formed in any suitable sequential orders.

Operations at block 126 may further include deposition of a contact etch stop layer (CESL) 250 over the source/drain features 246 and deposition of an interlayer dielectric (ILD) layer 252 over the CESL 250. Referring to FIGS. 18A-18B, the CESL 250 is deposited over the structure 200, including over the source/drain feature 246. The CESL 250 may include silicon nitride or aluminum nitride. In some implementations, the CESL 250 may be deposited using CVD or ALD. The ILD layer 252 is then deposited over the CESL 250. In some embodiments, the ILD layer 252 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 252 may be deposited using CVD, FCVD, spin-on coating, or a suitable deposition technique. After the deposition of the ILD layer 252, the structure 10 may be planarized by a planarization process to expose the dummy gate stacks 220. For example, the planarization process may include a chemical mechanical planarization (CMP) process. Exposure of the dummy gate stacks 220 allows the removal of the dummy gate stack 220.

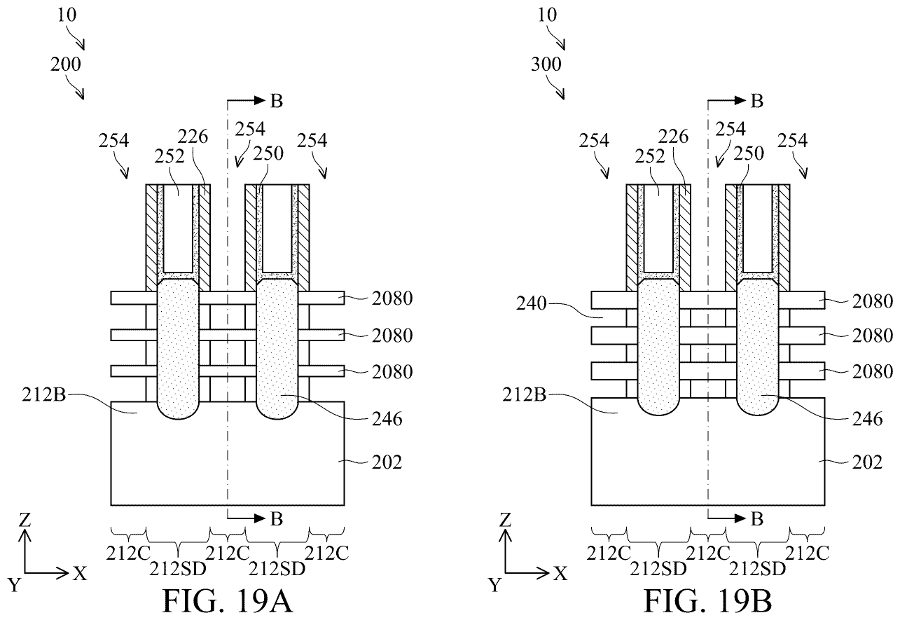

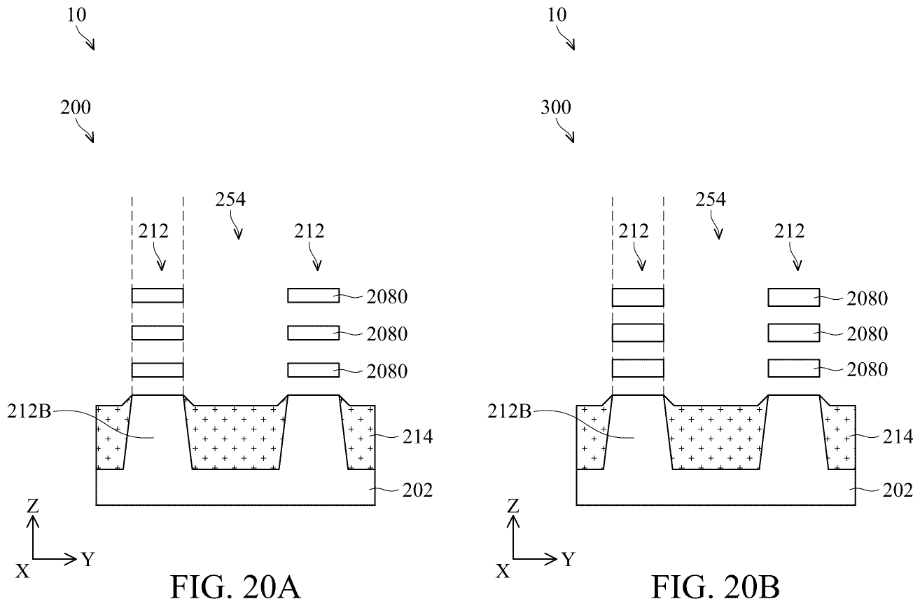

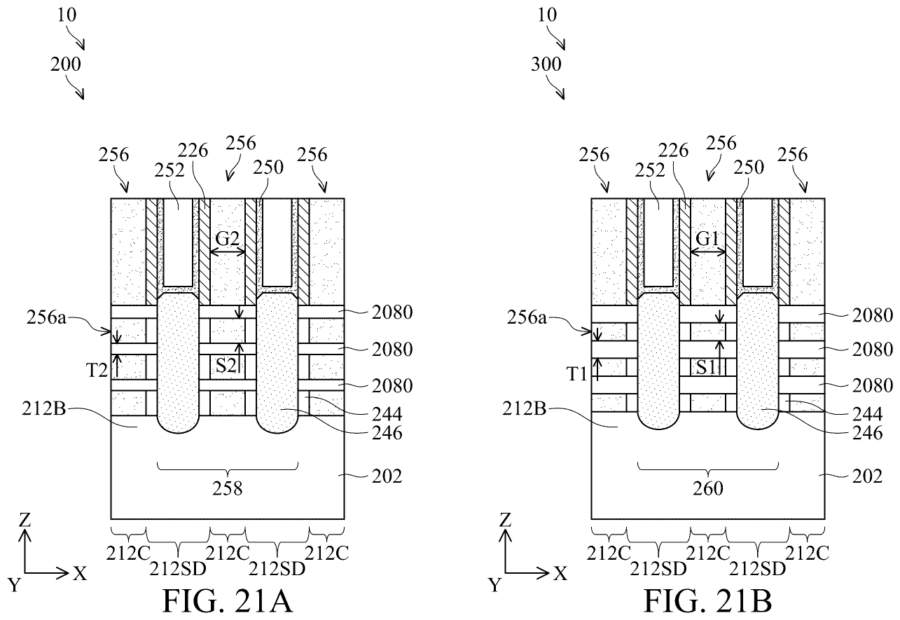

Referring to FIGS. 1 and 19A-21B, method 100 includes a block 128 where the dummy gate stacks 220 and the dummy layer 240 are replaced with gate structures 256. FIG. 20A illustrates a fragmentary cross-section view of the first region 200 taken along line B-B′ as in FIG. 19A. FIG. 20B illustrates a fragmentary cross-section view of the second region 300 taken along line B-B′ as in FIG. 19B. Operations at block 128 may include removal of the dummy gate stacks 220 (shown in FIGS. 19A-20B), removal of the dummy layer 240 (shown in FIGS. 19A-20B), and deposition of the gate structures 256 to wrap around each of the channel members 2080 (shown in FIGS. 21A-21B). In the first region 200, the gate structures 256 may form devices (e.g., transistor 258) with the active region 212. In the second region 300, the gate structures 256 may form devices (e.g., transistor 260) with the active region 212.

Referring to FIGS. 19A-20B, the dummy gate stacks 220 are removed. The removal of the dummy gate stacks 220 may include one or more etching processes that are selective to the material of the dummy gate stacks 220. For example, the removal of the dummy gate stacks 220 may be performed using a selective wet etch, a selective dry etch, or a combination thereof that is selective to the dummy gate stacks 220.

After the removal of the dummy gate stacks 220, sidewalls of the channel members 2080 and the dummy layer 240 in the channel region 212C are exposed. Referring to FIGS. 19A-20B, a separate etch process may be performed to selectively remove the dummy layer 240 in the channel region 212C. For example, a selective wet etch process or a selective dry etch process may be performed to remove the dummy layer 240. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. After the selective removal of the dummy layer 240, the channel members 2080 in the channel region 212C are once again exposed as shown in FIGS. 19A-20B. The selective removal of the dummy layer 240 forms gate trenches 254 that include openings 229 (or enlarged openings 229′) between adjacent channel members 2080. Because the germanium impurities are removed at blocks 112 and 116, channel width loss during operations at block 128 is negligible. In the depicted embodiments in FIGS. 20A-20B, sidewalls of the channel members 2080 and topmost portions of sidewalls of the base fin structure 212B therebelow align as shown by the dashed lines. The channel layers 2080 and the base fin structure 212B in the first region 200 may have profiles as described above in embodiments represented by FIGS. 12A, 13A-13B.

Referring to FIGS. 21A-21B, gate structures 256 are formed to wrap around each of released as channel members 2080. After the release of the channel members 2080, the gate structures 256 are formed to wrap around each of the channel members 2080. Although not explicitly shown in FIGS. 21A-21B, the gate structure 256 includes an interfacial layer interfacing the channel members 2080 and the base fin structure 212B in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 256 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure 256 includes portions 256a that interpose between the channel members 2080 in the channel region 212C.

The portions 256a in the first region 200 may have a height of S2 as described above, and the portions 256a in the second region 300 may have a height of S1 as described above. In some embodiment, the gate structure 256 has a width G2 and G1 along the X-direction in the first region 200 and the second region 300, respectively. G1 may be the same as or different from G2. In some embodiments, G1 is equal to G2. A ratio of T1 to G1 is about 0.3 to about 0.45, alternatively about 0.35 to about 0.45. A ratio of T2 to G2 is about 0.2 to about 0.4, alternatively about 0.2 to about 0.35. If the ratio of T2 to G2 is too small, for example, less than about 0.2, T2 may be too small, surface area of the channel members 2080 may be too small, short channel effect and Vt variation may be too much, impacting performance of the first region 200 and the overall performance of the structure 10.

The structure 10 may undergo further processing to form various features and regions known in the art. For example, subsequent processing may form additional interlayer dielectric (ILD) layer(s), contacts/vias/lines and multilayers interconnect features (e.g., metal layers and interlayer dielectrics) over the substrate 202, configured to connect the various features to form a functional circuit that may include one or more devices including the structure 10. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

FIG. 22 is a circuit diagram of an exemplary SRAM cell 40, which can be implemented as a memory cell in the first region 200 and further implemented in the semiconductor structure 10 in FIGS. 2A-2B. In the illustrated embodiment, the SRAM cell 400 is a single-port (SP) six-transistor (6T) SRAM cell. In various embodiments, the SRAM cell 400 may be other types of memory cells, such as dual-port memory cell or a memory cell having more than six transistors. FIG. 22 has been simplified for the sake of clarity to better understand the inventive concepts of the present disclosure. Additional features can be added in single-port SRAM cell 400, and some of the features described below can be replaced, modified, or eliminated in other embodiments of single-port SRAM cell 400.

The exemplary SRAM cell 400 is a single port SRAM cell that includes six transistors: a pass-gate transistor PG-1, a pass-gate transistor PG-2, a pull-up transistor PU-1, a pull-up transistor PU-2, a pull-down transistor PD-1, and a pull-down transistor PD-2. In operation, the pass-gate transistor PG-1 and the pass-gate transistor PG-2 provide access to a storage portion of the SRAM cell 400, which includes a cross-coupled pair of inverters, an inverter 462 and an inverter 466. The inverter 462 includes the pull-up transistor PU-1 and the pull-down transistor PD-1, and the inverter 466 includes the pull-up transistor PU-2 and the pull-down transistor PD-2. In some implementations, the pull-up transistors PU-1, PU-2 are configured as p-type FinFET transistors or p-type GAA transistors, and the pull-down transistors PD-1, PD-2 are configured as n-type FinFET transistors or n-type GAA transistors.

A gate of the pull-up transistor PU-1 interposes a source (electrically coupled with a power supply voltage (VDD)) and a first common drain (CD1), and a gate of pull-down transistor PD-1 interposes a source (electrically coupled with a power supply voltage (VSS), which may be an electric ground) and the first common drain. A gate of pull-up transistor PU-2 interposes a source (electrically coupled with the power supply voltage (VDD)) and a second common drain (CD2), and a gate of pull-down transistor PD-2 interposes a source (electrically coupled with the power supply voltage (VSS)) and the second common drain. In some implementations, the first common drain (CD1) is a storage node (SN) that stores data in true form, and the second common drain (CD2) is a storage node (SNB) that stores data in complementary form. The gate of the pull-up transistor PU-1 and the gate of the pull-down transistor PD-1 are coupled with the second common drain (CD2), and the gate of the pull-up transistor PU-2 and the gate of the pull-down transistor PD-2 are coupled with the first common drain (CD1). A gate of the pass-gate transistor PG-1 interposes a source (electrically coupled with a bit line BL) and a drain, which is electrically coupled with the first common drain (CD1). A gate of the pass-gate transistor PG-2 interposes a source (electrically coupled with a complementary bit line BLB) and a drain, which is electrically coupled with the second common drain (CD2). The gates of the pass-gate transistors PG-1, PG-2 are electrically coupled with a word line WL. In some implementations, the pass-gate transistors PG-1, PG-2 provide access to the storage nodes SN, SNB during read operations and/or write operations. For example, the pass-gate transistors PG-1, PG-2 couple the storage nodes SN, SNB respectively to the bit lines BL, BLB in response to a voltage applied to the gates of the pass-gate transistors PG-1, PG-2 by the word line WL.

FIG. 23 illustrates a fragmentary layout of the SRAM cell 400. The dashed rectangle presents border of the SRAM cell 400. In some embodiments, the SRAM cell 400 includes n-type three-dimensional active regions 212n (hereafter referred to as n-type active regions 212 n) each disposed in a p-type doped region (e.g., a P-well) 468P and p-type three-dimensional active regions 212p (hereafter referred to as p-type active regions 212p) each disposed in an n-type doped region (e.g., an N-well) 468N. The neighboring P-well 468P and N-well 468N may share a well border 470 as depicted. In some embodiments, the p-type active regions 212p and the n-type active regions 212n are similar to the active regions 212 in the first region 200 as described above. The p-type active regions 212p may have a width W1 along the Y-direction, the n-type active regions 212n may have a width W2 along the Y-direction. W2 may be greater than W1. The SRAM cell 400 includes gate structures 256-1 to 256-4 similar to the gate structures 256 in the first region 200 as described above and disposed over the n-type active regions 212n and/or the p-type active regions 212p to form various transistors such as pull-down transistors PD-1 and PD-2, pull-up transistors PU-1 and PU-2, and pass-gate transistors PG-1 and PG-2. The various transistors may be made similarly and have similar structures as the transistor 258 in the first region 200 described above. In such embodiments, the operations at block 114 forms the mask layer 232′ over the second region 300, but not over the first region 200 including the SRAM cell 400.

FIGS. 24A-24B illustrate fragmentary top views of an alternative structure 20 upon completion of the operations at block 114 according to some embodiments of method 100 in FIG. 1. A difference from the embodiments of forming the structure 10 includes that, in the depicted embodiment, the mask layer 232′ is further formed over the N-well(s) 468N in the first region 200, leaving sub-regions of the P-wells 468P in the first region 200 exposed. In other words, at block 114 of method 100, the second area further includes sub-regions of the N-well(s) 468N in the first region 200, and the first area includes the sub-regions of the P-wells 468P in the first region 200. In such embodiments, the mask layer 232′ may have a stripe pattern in the first region 200 from a top view as in FIGS. 24A-24B and include stripe portions 232a′. The stripe portions 232a′ may each extend lengthwise along the X-direction and are spaced apart from each other along the Y-direction from the top view. In such embodiments, the channel members 2080 over the N-well(s) 468N are protected by the mask layer 232′ from the etching process 238 at block 116. A difference from the structure 10 includes that, the p-type transistors over the N-well(s) 468N (e.g., the pull-up transistors PU-1 and PU-2) are made similarly and have similar structures as the transistor 260 in the second region 300 in FIGS. 3-21B.

FIG. 25 illustrates a fragmentary cross-sectional view of the SRAM cell 400 taken along line C-C′ as in FIG. 24A. As depicted, the channel members 2080 of the pull-down transistor PD-1 and the pass-gate transistor PG-2 have the thickness T2 as described above, and the channel members 2080 over the N-well 268N, such as the channel members 2080 of the pull-up transistor PU-1 have the thickness T1 as described above. The SRAM cell 400 includes a gate isolation structure 480 between the gate structure 256-3 and the gate structure 256-4. A top surface of the base fin structure 212B over the P-well 468P is lower than a top surface of the base fin structure 212B over the N-well 468N.

Additional benefits as compared to the structure 10 may include that, maximum voltage level Vmax of the SRAM cell 400 may be improved, and overall performance of the structure 20 may be further improved from the structure 10.

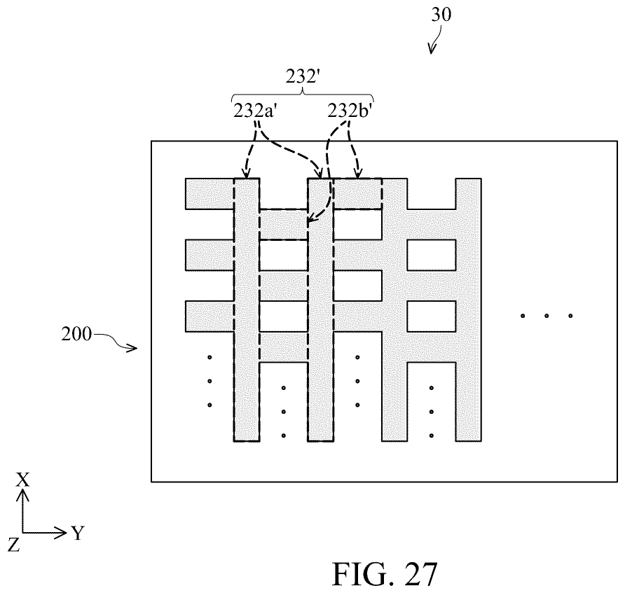

FIGS. 26-27 illustrate fragmentary top views of another alternative structure 30 upon completion of the operations at block 114 according to some embodiments of method 100 in FIG. 1. Four of the SRAM cells 400 are in FIG. 26 as an example. A difference from the embodiments of forming the structure 20 includes that, in the depicted embodiment, the mask layer 232′ is further formed over sub-regions where the pull-down transistors are formed in the first region 200, leaving sub-regions where the pass-gate transistors are formed in the first region 200 exposed. In other words, at block 114 of method 100, the second area further includes the sub-regions where the pull-down transistors are formed in the first region 200, and the first area includes the sub-regions where the pass-gate transistors are formed in the first region 200. In such embodiments, the mask layer 232′ may have a stripe-checkerboard pattern in the first region 200 from a top view as in FIGS. 26-27. A difference from the embodiments represented by FIGS. 24A-25 includes that, from the top view, besides the stripe portions 232a′, the mask layer 232′ further includes rectangle portions 232b′ protruding from the stripe portion 232a′ and/or connecting neighboring stripe portions 232a′. The rectangle portions 232b′ form a checkerboard pattern. Sidewalls (e.g., 232s-1 and 232s-2 in FIG. 26) of adjacent rectangle portions 232b′ connected to the same stripe portion 232a′ may align along the Y-direction. In such embodiments, the channel members 2080 in the sub-regions where the pull-down transistors are formed in the first region 200 are protected by the mask layer 232′ from the etching process 238 at block 116. A difference from the structure 20 includes that, the pull-down transistors (e.g., PD-1, PD-2) are made similarly and have similar structures as the transistor 260 in the second region 300 in FIGS. 3-21B.

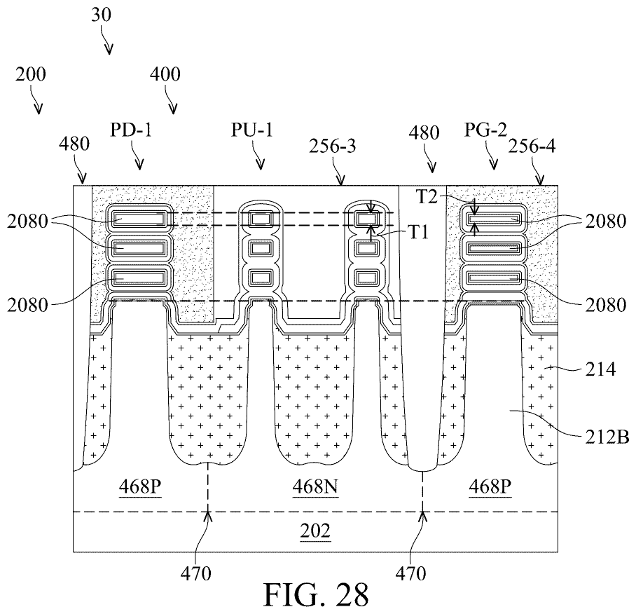

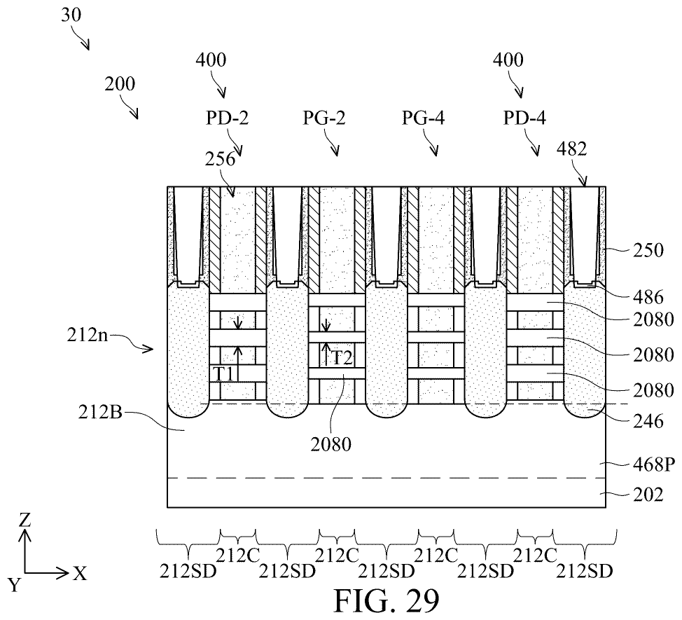

FIGS. 28 and 29 illustrate fragmentary cross-sectional views of the structure 30 taken along line C-C′ and line D-D′, respectively, as in FIG. 26. As depicted, the channel members 2080 of the pass-gate transistors (e.g., PG-2, PG-4) have the thickness T2 as described above. The channel members 2080 of the pull-down transistors (e.g., PD-1, PD-2, PD-4) and the channel members 2080 over the N-well 268N, such as the channel members 2080 of the pull-up transistor PU-1 have the thickness T1 as described above. In the depicted embodiment, top surfaces of the base fin structures 212B of the pass-gate transistors are lower than top surfaces of the base fin structures 212B of the pull-up transistors and the pull-down transistors. Referring to FIG. 29, the SRAM 400 further includes source/drain contacts 482 over the source/drain features 246. In some embodiments, the SRAM 400 further includes a silicide layer 486 disposed between the source/drain contact 482 and the source/drain feature 246 therebelow.

Additional benefits as compared to the structure 10 may include that, a beta ratio of the SRAM cell 400 may be improved, a ratio of a saturation current of the pull-down transistors to a saturation current of the pass-gate transistors may be greater than 1, Vmax of the SRAM cell 400 may be improved, and overall performance of the structure 30 may be further improved from the structure 10. The beta ratio is the ratio of the drive current of pull-down transistors to the drive current of the respective pass-gate transistors in an SRAM cell. The beta ratio affects the stability of an SRAM cell.

FIGS. 30A-30B illustrate fragmentary top views of another alternative structure 40 upon completion of the operations at block 114 according to some embodiments of method 100 in FIG. 1. A difference from the embodiments of forming the structure 10 includes that, in the depicted embodiment, the mask layer 232′ is further formed over the P-wells 468P in the first region 200, leaving sub-regions of the N-well(s) 468N in the first region 200 exposed. In other words, at block 114 of method 100, the second area further includes the sub-regions of the P-wells 468P in the first region 200, and the first area includes the sub-regions of the N-well(s) 468N in the first region 200. In such embodiments, the mask layer 232′ may have a stripe pattern in the first region 200 from a top view as in FIGS. 30A-30B and include stripe portions 232c′. The stripe portions 232c′ may each extend lengthwise along the X-direction and are spaced apart from each other along the Y-direction from the top view. In FIG. 30A, each of the rectangle labeled as 232c′ may be about half of a stripe portion 232c′ as in FIG. 30B, the rectangle labeled as 232c′ in FIG. 30A may merge with that of a neighboring SRAM cell to form the stripe portion 232c′ as in FIG. 30B. In such embodiments, the channel members over the P-wells 468P are protected by the mask layer 232′ from the etching process at block 116. A difference from the structure 10 includes that, the n-type transistors over the P-wells 468P (e.g., the pull-down transistors PD-1 and PD-2, the pass-gate transistors PG-1 and PG-2) are made similarly and have similar structures as the transistor 260 in the second region 300 in FIGS. 3-21B.

FIG. 31 illustrates a fragmentary cross-sectional view of the SRAM cell 400 taken along line C-C′ as in FIG. 30A. As depicted, the channel members 2080 of the pull-down transistor PD-1 and the pass-gate transistor PG-2 have a thickness T5 (or sheet height) along the Z-direction, and the channel members 2080 over the N-well 268N, such as the channel members 2080 of the pull-up transistor PU-1 have a thickness (or sheet height) T6 along the Z-direction. A ratio of T6 to T5 is about 0.5 to 1, alternatively about 0.7 to 1. T6 may be in a range of about 3 nm to about 5 nm, alternatively about 4 nm to about 5 nm. The SRAM cell 400 includes a gate isolation structure 480 between the gate structure 256-3 and the gate structure 256-4. A top surface of the base fin structure 212B over the P-well 468P is higher than a top surface of the base fin structure 212B over the N-well 468N.

Additional benefits as compared to the structure 10 may include that, Vmin of the SRAM cell 400 may be reduced while keeping relatively low resistance of the channel members 2080 of the n-type transistors in the SRAM cell 400.

In some embodiments, the SRAM cell 400 may be other types of memory cells, such as a two-port SRAM cell that includes seven transistors (7T) or eight transistors (8T). The embodiments described above may be applicable when the SRAM cell 400 is other types of memory cells. For example, method 100 includes forming the mask layer 232′ in the second region 300 and optionally certain sub-regions (e.g., sub-regions where p-type transistors are formed) of the other types of memory cells in the first region 200 similar as described above. Thus, in such embodiments, the channel members 2080 in different regions and/or sub-regions may have different dimensions (e.g., thicknesses) similar as described above.

Referring to FIG. 32, in some embodiments, the two-port SRAM cell 400 includes seven transistors. The two-port SRAM cell 400 may include a write port portion 400W. In the present embodiments, the write port portion 400W includes pull-up transistors PU-1, PU-2, pull-down transistors PD-1, PD-2, and pass-gate transistors PG-1, PG-2. In the illustrated embodiment, transistors PU-1 and PU-2 are p-type transistors, and transistors PG-1, PG-2, PD-1, and PD-2 are n-type transistors. The drains of the pull-up transistor PU-1 and the pull-down transistor PD-1 are coupled together, and the drains of the pull-up transistor PU-2 and the pull-down transistor PD-2 are coupled together. The transistors PU-1 and PD-1 are cross-coupled with the transistors PU-2 and PD-2 to form a data latch. The gates of the transistors PU-1 and PD-1 are coupled together and to the common drains of the transistors PU-2 and PD-2 to form a storage node SN, and the gates of the transistors PU-2 and PD-2 are coupled together and to the common drains of the transistors PU-1 and PD-1 to form a complementary storage node SNB. Sources of the pull-up transistors PU-1 and PU-2 are coupled to a power line configured to provide a first voltage VDD (this power line may be referred to as a VDD line), and the sources of the pull-down transistors PD-1 and PD-2 are coupled to a power line configured to provide a second voltage VSS (this power line may be referred to as a VSS line), which may be an electrical ground in some embodiments.

The storage node SN of the data latch is coupled to a bit line W_BL of the write port portion 400W (may be referred to as a write bit line W_BL or a write-port bit line W_BL) through the pass-gate transistor PG-2, and the complementary storage node SNB is coupled to a complementary bit line W_BLB of the write port portion 400W (may be referred to as a complementary write bit line W_BLB or a complementary write-port bit line W_BLB) through the pass-gate transistor PG-1. The storage node SN and the complementary storage node SNB are complementary nodes that are often at opposite logic levels (logic high or logic low). Gates of the pass-gate transistors PG-1 and PG-2 are coupled to a word line W_WL of the write port portion 400W (may be referred to as a write word line W_WL or a write-port word line W_WL).

The two-port SRAM cell 400 also includes a read port portion 400R coupled to the write port portion 400W. The read port portion 400R of the SRAM cell 400 includes a read-port pass-gate transistor R-PG. One source/drain terminal (e.g., a source terminal) of the read-port pass-gate transistor R-PG is electrically coupled to a bit line R_BL of the read port portion 400R. The bit line of the read port portion 400R may be referred to as a read-port bit line R_BL or a read bit line R_BL. The other source/drain terminal (e.g., a drain terminal) of the read-port pass-gate transistor R-PG is electrically coupled to the storage node SN (or to the gates of the transistors PU-1 and PD-1). The gate of the read-port pass-gate transistor R-PG is coupled to a word line R_WL of the read port portion 400R. The word line R_WL of the read port portion 400R may be referred to as a read word line R_WL or a read-port word line R_WL. In the illustrated embodiment, the transistor R-PG is a p-type transistor. That is, in the two-port SRAM cell 400, the pass-gate transistors in the write port portion 400W are n-type transistors, and the pass-gate transistor in read port portion 400R is a p-type transistor.

Although not intended to be limiting, one or more embodiments of the present disclosure provide many benefits to a semiconductor device. For example, by performing additional etching process to the channel members in certain areas of a semiconductor structure and replacing the sacrificial layers with a dummy layer, the channel members in different areas may have different thicknesses to implement different functions, and impurities in the channel members are reduced. For example, uniformity of channel member thickness may be improved; Vt variation, short channel effect, and Vmin of memory cells in a memory region may be improved; and channel resistance of the channel members in a logic region is relatively low. Thus, the overall performance of the semiconductor device may be improved.

In one exemplary aspect, the present disclosure is directed to a method. The method includes providing a structure. The structure includes a substrate, a first stack of alternating first channel layers and first sacrificial layers over the substrate, a first source/drain trench exposing sidewalls of the first sacrificial layers, a second stack of alternating second channel layers and second sacrificial layers over the substrate, and a second source/drain trench exposing sidewalls of the second sacrificial layers. The method further includes performing a first etching process to selectively remove the first sacrificial layers and the second sacrificial layers, performing a second etching process to the first channel layers but not the second channel layers, forming a first source/drain feature in the first source/drain trench and a second source/drain feature in the second source/drain trench, and forming a first gate structure wrapping around the first channel layers and a second gate structure wrapping around the second channel layers.

In some embodiments, performing the second etching process to the first channel layers but not the second channel layers includes forming a mask material over the first channel layers and the second channel layers, forming a patterned photoresist layer over a first portion of the mask material over the second channel layers, etching a second portion of the mask material over the first channel layers using the patterned photoresist layer as an etch mask, thereby removing the second portion of the mask material, and etching the first channel layers. In some embodiments, performing the second etching process reduces a first thickness of the first channel layers to be less than a second thickness of the second channel layers. In some embodiments, the method further includes after performing the second etching process, forming a dummy layer around the first channel layers and the second channel layers, and after forming the first source/drain feature in the first source/drain trench and the second source/drain feature in the second source/drain trench, removing the dummy layer. In some embodiments, the method further includes selectively and partially recessing the dummy layer to form first inner spacer recesses among the first channel layers and second inner spacer recesses among the second channel layers, and forming first inner spacer features in the first inner spacer recesses and second inner spacer features in the second inner spacer recesses. At least one of the first inner spacer features have a first thickness and at least one of the second inner spacer features have a second thickness less than the first thickness. In some embodiments, the second source/drain feature is connected to the first channel layers and the second channel layers. In some embodiments, the first channel layers are of a first transistor, and the second channel layers are of a second transistor, the first transistor and the second transistor are of a same static random-access memory (SRAM) cell. In some embodiments, performing the second etching process removes a top portion of the substrate below the first channel layers.

In another exemplary aspect, the present disclosure is directed to a method. The method includes forming a first region and a second region over a substrate. The first region includes a first stack of alternating first channel layers and first sacrificial layers, and the second region includes a second stack of alternating second channel layers and second sacrificial layers. The method further includes forming a first dummy gate structure over the first stack of alternating first channel layers and first sacrificial layers and a second dummy gate structure over the second stack of alternating second channel layers and second sacrificial layers, forming a first source/drain recess in the first stack of alternating first channel layers and first sacrificial layers and adjacent to the first dummy gate structure, forming a second source/drain recess in the second stack of alternating second channel layers and second sacrificial layers and adjacent to the second dummy gate structure, selectively removing the first sacrificial layers and the second sacrificial layers to release the first channel layers and the second channel layers, forming a mask layer over the second region but not the first region, removing a portion of the first channel layers, thereby reducing a thickness of the first channel layers, removing the mask layer, depositing a first dummy layer around the first channel layers and a second dummy layer around the second channel layers, forming a first source/drain feature in the first source/drain recess and a second source/drain feature in the second source/drain recess, and replacing the first dummy gate structure and the first dummy layer with a first metal gate structure and replacing the second dummy gate structure and the second dummy layer with a second metal gate structure.

In some embodiments, the mask layer forms a stripe pattern from a top view. In some embodiments, the first region is surrounded by the second region from a top view. In some embodiments, the first region includes a memory region and the second region includes a logic region. In some embodiments, forming the mask layer over the second region but not the first region includes depositing a mask material over the first region and the second region, forming a patterned photoresist layer over the second region, and removing the mask material from the first region using the patterned photoresist layer as an etch mask. A remaining portion of the mask material over the second region forms the mask layer. In some embodiments, the first source/drain feature and the second source/drain feature are of different conductivity types. In some embodiments, removing the portion of the first channel layers includes performing a wet etching process to the first channel layers.

In yet another exemplary aspect, the present disclosure is directed to a semiconductor structure. The semiconductor structure includes a substrate, a first stack of first channel layers disposed over the substrate, a first source/drain feature connected to the first stack of first channel layers, a second stack of second channel layers disposed over the substrate, a second source/drain feature connected to the second stack of second channel layers, and a metal gate structure wrapping around the first channel layers and extending lengthwise along a direction. Aat least one of the first channel layers have a first thickness and a first width along the direction, at least one of the second channel layers have a second thickness and a second width along the direction, and the second thickness is greater than the first thickness, and the second width is equal to or less than the first width.

In some embodiments, the semiconductor structure further includes a second metal gate structure wrapping around the second channel layers. In some embodiments, the first metal gate structure further wraps around the second channel layers. In some embodiments, the second source/drain feature is connected to the first stack of first channel layers. In some embodiments, a ratio of the first thickness to the second thickness is about 0.7 to about 1.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a structure including:
a substrate,
a first stack of alternating first channel layers and first sacrificial layers over the substrate,
a first source/drain trench exposing sidewalls of the first sacrificial layers,
a second stack of alternating second channel layers and second sacrificial layers over the substrate, and
a second source/drain trench exposing sidewalls of the second sacrificial layers;
performing a first etching process to selectively remove the first sacrificial layers and the second sacrificial layers;
performing a second etching process to the first channel layers but not the second channel layers;
forming a first source/drain feature in the first source/drain trench and a second source/drain feature in the second source/drain trench; and
forming a first gate structure wrapping around the first channel layers and a second gate structure wrapping around the second channel layers.

2. The method of claim 1, wherein performing the second etching process to the first channel layers but not the second channel layers includes:
forming a mask material over the first channel layers and the second channel layers,
forming a patterned photoresist layer over a first portion of the mask material over the second channel layers,
etching a second portion of the mask material over the first channel layers using the patterned photoresist layer as an etch mask, thereby removing the second portion of the mask material, and
etching the first channel layers.

3. The method of claim 1, wherein performing the second etching process reduces a first thickness of the first channel layers to be less than a second thickness of the second channel layers.

4. The method of claim 1, further comprising:
after performing the second etching process, forming a dummy layer around the first channel layers and the second channel layers, and
after forming the first source/drain feature in the first source/drain trench and the second source/drain feature in the second source/drain trench, removing the dummy layer.

5. The method of claim 4, further comprising:
selectively and partially recessing the dummy layer to form first inner spacer recesses among the first channel layers and second inner spacer recesses among the second channel layers, and
forming first inner spacer features in the first inner spacer recesses and second inner spacer features in the second inner spacer recesses,
wherein at least one of the first inner spacer features have a first thickness and at least one of the second inner spacer features have a second thickness less than the first thickness.

6. The method of claim 1, wherein the second source/drain feature is connected to the first channel layers and the second channel layers.

7. The method of claim 1, wherein the first channel layers are of a first transistor, and the second channel layers are of a second transistor,
wherein the first transistor and the second transistor are of a same static random-access memory (SRAM) cell.

8. The method of claim 1, wherein performing the second etching process removes a top portion of the substrate below the first channel layers.

9. A method, comprising:
forming a first region and a second region over a substrate,
wherein the first region includes a first stack of alternating first channel layers and first sacrificial layers, and
wherein the second region includes a second stack of alternating second channel layers and second sacrificial layers;
forming a first dummy gate structure over the first stack of alternating first channel layers and first sacrificial layers and a second dummy gate structure over the second stack of alternating second channel layers and second sacrificial layers;
forming a first source/drain recess in the first stack of alternating first channel layers and first sacrificial layers and adjacent to the first dummy gate structure;
forming a second source/drain recess in the second stack of alternating second channel layers and second sacrificial layers and adjacent to the second dummy gate structure;
selectively removing the first sacrificial layers and the second sacrificial layers to release the first channel layers and the second channel layers;
forming a mask layer over the second region but not the first region;
removing a portion of the first channel layers, thereby reducing a thickness of the first channel layers;
removing the mask layer;
depositing a first dummy layer around the first channel layers and a second dummy layer around the second channel layers;
forming a first source/drain feature in the first source/drain recess and a second source/drain feature in the second source/drain recess; and
replacing the first dummy gate structure and the first dummy layer with a first metal gate structure and replacing the second dummy gate structure and the second dummy layer with a second metal gate structure.

10. The method of claim 9, wherein the mask layer forms a stripe pattern from a top view.

11. The method of claim 9, wherein the first region is surrounded by the second region from a top view.

12. The method of claim 9, wherein the first region includes a memory region and the second region includes a logic region.

13. The method of claim 9, wherein forming the mask layer over the second region but not the first region includes:
depositing a mask material over the first region and the second region,
forming a patterned photoresist layer over the second region, and
removing the mask material from the first region using the patterned photoresist layer as an etch mask,
wherein a remaining portion of the mask material over the second region forms the mask layer.

14. The method of claim 9, wherein the first source/drain feature and the second source/drain feature are of different conductivity types.

15. The method of claim 9, wherein removing the portion of the first channel layers includes performing a wet etching process to the first channel layers.

16. A semiconductor structure, comprising:
a substrate;
a first stack of first channel layers disposed over the substrate;
a first source/drain feature connected to the first stack of first channel layers;
a second stack of second channel layers disposed over the substrate;
a second source/drain feature connected to the second stack of second channel layers; and
a metal gate structure wrapping around the first channel layers and extending lengthwise along a direction,
wherein at least one of the first channel layers have a first thickness and a first width along the direction,
wherein at least one of the second channel layers have a second thickness and a second width along the direction, and
wherein the second thickness is greater than the first thickness, and the second width is equal to or less than the first width.

17. The semiconductor structure of claim 16, further comprising a second metal gate structure wrapping around the second channel layers.

18. The semiconductor structure of claim 16, wherein the first metal gate structure further wraps around the second channel layers.

19. The semiconductor structure of claim 16, wherein the second source/drain feature is connected to the first stack of first channel layers.

20. The semiconductor structure of claim 16, wherein a ratio of the first thickness to the second thickness is about 0.7 to about 1.
